(19) United States
(12) Patent Application Publication
(10) Pub. No.: US 2025/0095928 A1
(43) Pub. Date: Mar. 20, 2025

(54) SWITCHING DEVICE AND METHOD OF PRODUCING A ROTARY SHAFT FOR THE SWITCHING DEVICE

(71) Applicant: Siemens Aktiengesellschaft, München (DE)

(72) Inventor: Matthias Eisner, Neukirchen (DE)

(21) Appl. No.: 18/888,373

(22) Filed: Sep. 18, 2024

(30) Foreign Application Priority Data
Sep. 18, 2023 (DE) 10 2023 209 036.8

(51) Int. Cl. H01H 9/02; H01H 11/00

(52) U.S. Cl. CPC H01H 9/02; H01H 11/00

(57) ABSTRACT

A switching device has a housing with an air duct extending between a ventilation opening in a bottom wall and a ventilation opening in a top wall. A rotary shaft extends from a front wall to a rear wall and is rotatably mounted for rotating a coupling device in order to fasten the switching device to a corresponding receiving device. The rotary shaft, which is formed as a hollow shaft, has a middle portion between a first and a second end portion. The middle portion which extends through the ventilation air duct has an outer diameter d. A ratio D/d of a clear width of the air duct and the outer diameter d of the middle portion of the hollow shaft is greater than 1.5.

### CROSS-REFERENCE TO RELATED APPLICATION

This application claims the priority, under 35 U.S.C. § 119, of German Patent Application DE 10 2023 209 036.8, filed Sep. 18, 2023; the prior application is herewith incorporated by reference in its entirety.

### FIELD AND BACKGROUND OF THE INVENTION

The present invention relates to a switching device and to a method for producing a rotary shaft for a switching device.

A SIMATIC® ET 200SP motor starter from Siemens AG, i.e., a switching device for starting and stopping a motor, is mounted on a corresponding, fully wired mounting base (“BaseUnit”) by first bringing a mechanical twist lock of the motor starter into a mounting/dismounting position (FIG. 1), then the motor starter is guided onto the mounting base (FIG. 1) and finally the twist lock is turned clockwise into the operating position (FIGS. 2 and 3), in which the motor starter is firmly locked in the mounting base and all electrical contacts are connected; see chapter 6.14.2 “Installing/uninstalling the motor starter” in: System Manual “SIMATIC ET 200SP Decentralized Peripheral System”, Edition 02/2018 (February 2018), A5E03576848-AH, Siemens AG, Division Digital Factory, Nuremberg, Germany.

The mechanical twist lock is designed as a solid shaft made of plastic (FIG. 5). The solid shaft is mounted in a front wall and in a rear wall of the motor starter housing, has a toggle for manual operation at one end protruding from the front wall and has a retaining lug at its other end protruding from the rear wall. The retaining lug can engage in a corresponding groove in the mounting base, in the manner of a bayonet catch (FIG. 6). The solid shaft has a relatively large diameter to ensure the necessary torsional rigidity: When actuating the toggle, torques of up to 2 Nm can occur at times.

Due to its large diameter, however, the solid shaft prevents cooling air from flowing through the motor starter to dissipate the heat generated in the motor starter. For this reason, continuous air ducts are provided in the solid shaft transverse to its longitudinal axis (FIG. 7), which improve air convection.

High currents can occur in modern motor starters with powerful electronics, e.g., motor starting currents of >>50 A for a few seconds. These periodically occurring short-term currents, but also long-term continuous currents, generate a relatively high heat loss. The dissipation of such a large heat output from a motor starter or—more generally speaking—from a switching device can cause problems if the air convection in the switching device is obstructed by a voluminous solid shaft.

### SUMMARY OF THE INVENTION

It is accordingly an object of the invention to provide a switching device with a rotary shaft which overcome the above-mentioned disadvantages of the heretofore-known devices and methods of this general type and which address the problem of modifying a mechanical twist lock of a switching device in such a way that increased heat dissipation from the switching device is possible.

With the above and other objects in view there is provided, in accordance with the invention, a switching device, comprising:
a housing having a front wall, a rear wall opposite the front wall, a top wall and a bottom wall opposite the top wall, and two opposing side walls, and wherein an air duct is formed in the housing running parallel to the side walls and having a clear width D, measured in a direction transverse to the side walls;
a rotary shaft extending from the front wall, through the housing, and to the rear wall, the rotary shaft having a first end portion rotatably mounted the front wall and a second end portion rotatably mounted in the rear wall;
the rotary shaft carrying a rotary device at an end of the first end portion which is connected for conjoint rotation with the rotary shaft and which is accessible on an outer side of the front wall, and the rotary shaft carrying a coupling device at an end of the second end portion which is connected for conjoint rotation with the rotary shaft and which is configured for fastening the switching device to a corresponding receiving device;
each of the bottom wall and the top wall being formed with at least one ventilation opening, enabling an air stream to flow in the air duct from the ventilation opening of the bottom wall to the ventilation opening of the top wall;
the rotary shaft having a middle portion between the first and second end portions;
the middle portion of the rotary shaft extending in the air duct the middle portion having an outer diameter d; and
the rotary shaft being a hollow shaft and a ratio D/d of the clear width D of the air duct to the outer diameter d is greater than 1.5.

In other words, the switching device according to the invention has a housing. The housing has a front wall and a rear wall opposite the front wall, a top wall and a bottom wall opposite the top wall, as well as two opposing side walls. The front wall is the wall at the front of the housing where an operator can make inputs, e.g. test button, reset button, and receive outputs, e.g. LEDs for status and error display. The rear wall is the wall at the back of the housing. The bottom wall is the wall of the housing facing the floor.

An air duct that runs parallel to the side walls is formed inside the housing. The air duct has a clear width D, measured in a direction transverse to the side walls.

The switching device according to the invention has a rotary shaft that extends from the front wall through the housing to the rear wall. The rotary shaft has a first end portion that is rotatably mounted in the front wall. The rotary shaft has a second end portion that is rotatably mounted in the rear wall. At the end of its first end portion, the rotary shaft carries a rotary device, e.g. a rotary toggle, which is connected for conjoint rotation to the rotary shaft and is accessible on the outer side of the front wall. In addition, at the end of its second end portion, the rotary shaft carries a coupling device which is connected for conjoint rotation to the rotary shaft and is accessible on the outside of the rear wall. The switching device can be attached to a corresponding receiving device with the aid of the coupling device. This is why the rotary shaft is also referred to as the “coupling shaft”.

The bottom wall and the top wall each have at least one ventilation opening, so that an air stream can flow in the air duct from the ventilation opening of the bottom wall to the ventilation opening of the top wall. The direction of an air stream passing through the air duct is from the bottom wall to the top wall, as the air stream absorbs heat from the heat-emitting electronic components inside the housing and is therefore warmer than the surroundings: thus the heated air of the air stream rises from the bottom to the top according to the natural convection in the air duct. If heat dissipation is to be increased by convection, a fan can also cause forced convection through the air duct. At low currents, heat dissipation via free convection is usually sufficient; at higher currents, a fan is also used.

The rotary shaft has a middle portion located between the first end portion and the second end portion. The middle portion is located in the air duct and has an outer diameter d. The size ratio D/d, i.e. the quotient of the clear width D of the duct and the outer diameter of the middle portion of the rotary shaft located in the air duct, is greater than 1.5. The rotary shaft is also designed as a hollow shaft.

The problem is also solved in accordance with the invention by a method for producing a rotary shaft for a switching device according to the invention. A metal middle piece is fed to an injection molding machine as an insert during an injection-molding process and a plastics end piece is injection-molded on at both ends of the middle piece.

The invention is based on the realization that hollow shafts have clear advantages over solid shafts in terms of torsional rigidity. The following example from the website https://technikdoku.com/torsion/(retrieved Jul. 24, 2023, 15:00 CEST) illustrates this: a solid shaft and a hollow shaft are compared. The solid shaft has a diameter of Dm=40 mm (cross-sectional area A1=1256 mm²), the hollow shaft has an outer diameter Dm=70 mm and an inner diameter dm=57 mm (cross-sectional area A2=1297 mm²). The cross-sectional areas of the two shafts are therefore substantially identical (i.e., a difference of only 3%). Each of the shafts is loaded with a torque (torsional moment) M_t=700 Nm. Although the cross-sectional areas of the shafts differ only insignificantly, the torsional stresses T_t occurring in the shafts are considerably different: for the solid shaft, calculated using the formula Tt=(16 M_t)/(π Dm³), the torsional stress is Tt=56 N/mm²; for the hollow shaft, calculated using the formula Tt=(16 D M_t)/(TT (Dm⁴-dm⁴)), the torsional stress is Tt=19 N/mm². This example therefore illustrates that hollow shafts can transmit considerably greater torsional moments (=torques) than solid shafts for the same weight. Or, to put it another way: A hollow shaft, which can be loaded with the same torsional moment as a solid shaft, has a smaller outer diameter than the solid shaft.

In the invention, the realization that hollow shafts have clear advantages over solid shafts in terms of torsional rigidity is used to move in a new direction with regard to the rotary shaft, which differs fundamentally from the prior art strategy. In the past, the diameter of the solid rotary shaft was made as large as possible in order to achieve sufficient torsional rigidity; it was attempted to use through-openings in the rotary shaft in order to compensate as well as possible for the blockage of the air duct caused by the voluminous rotary shaft. According to the present invention, a rotary shaft designed as a hollow shaft is used and the outer diameter of the rotary shaft is made as small as possible. This makes it possible for the hollow-shaft rotary shaft to block only a much smaller region of the air duct than with the conventional solid-shaft rotary shaft; in addition, the smaller outer diameter enables a lateral flow around the rotary shaft, i.e. the air stream can be directed almost unhindered through the control device.

By reducing the diameter of the rotary shaft, especially in the middle portion of the rotary shaft, installation space is saved, the switching device can be made smaller, or larger electronic heat sinks can be used with the same installation space.

In addition, flat flow resistances, in this case in the form of blind holes in the conventional rotary shaft, are avoided. The cooling air can therefore flow unhindered past the outside of the rotary shaft according to the invention, as the smaller outer diameter of the rotary shaft in combination with the position of the rotary shaft in the switching device is selected so that the rotary shaft has a much smaller negative influence on the cooling capacity of the cooling channel.

To couple the front toggle with the rear mounting base, a large-diameter rotary shaft designed as a solid shaft has been used to date, which has ventilation ducts and material cut-outs in the form of blind holes. Due to the central position in the switching device, the ventilation of the switching device is restricted by the previous rotary shaft. The invention replaces the previous rotary shaft with a tubular rotary shaft. As a result, the production-related requirement for thin, uniform wall thicknesses can be met and the outer diameter is also greatly reduced. The mechanical stresses caused by the torsion of the rotary shaft are kept sufficiently low despite the reduction of the effective outer diameter by designing the rotary shaft as a hollow shaft.

Due to the smaller diameter of the rotary shaft, material clearances are no longer required in the rotary shaft. The result is a uniformly smooth, circular surface that does not present any resistance to the air flow. Reducing the outer diameter means that the rotary shaft no longer plays a significant role in terms of flow resistance in the air duct.

Advantageous embodiments and developments of the invention are specified in the dependent claims.

According to a preferred embodiment of the invention, the ratio D/d lies between 1.8 and 2.2. As a result, the rotary shaft is only in the air stream in half of the air duct; this enables a very good lateral flow around the rotary shaft.

According to a preferred embodiment of the invention, the air duct is bounded on the one hand by a first printed circuit board arranged in the housing parallel to a first of the two side walls, on which electronic components and heat sinks are arranged, and on the other hand by a second plate arranged parallel to a second of the two side walls, wherein the clear width D of the air duct is defined by the distance between the first printed circuit board and the second plate. For higher currents, heat sinks, usually made of aluminum, are used; these are connected to the electronic components in a thermally conductive manner. Due to the rotary shaft with reduced outer diameter according to the invention, there are no significant structural flow resistances in the line of action “air inlet (fan)=>heat-emitting electronic components (e.g. semiconductors)=>heat sink=>air outlet.”

The heat loss from electronic components must be dissipated in order to prevent overheating and thus destruction of the electronic components. The problem of sufficient heat dissipation from electronic components becomes particularly critical when the installation space for the electronic components is limited and when there is an increased current, e.g. when a motor starts up. The power semiconductors installed in the switching device are the largest source of heat. The temperature development that occurs during continuous operation or motor start-up operation is decisive for the further design of electronic and mechanical components as well as for the classification of the operating conditions (rated current, starting current, permissible ambient temperature, etc.).

The switching device according to the invention has at least one electronic component. A component in electrical engineering and electronics, in short: electronic component, is understood to be the smallest unit in a circuit that cannot be broken down further (DIN 40150:1979-10 Terms for classifying functional and construction units), e.g. a resistor. An electronic component can be a passive electronic component, such as a resistor, a coil or a capacitor. An electronic component can also be an active electronic component, such as a transistor (IGBT, FET, MOSFET, etc.), a diode, a rectifier, a processor/IC (=integrated circuit), an LED. An electronic component can also be a power electronics component. Electronic components can be, for example, diacs, triacs, transistors, MOSFETs, IGBTs, thyristors, diodes, capacitors, etc. in power electronics, as well as components in control electronics such as controllers, voltage regulators, resistors, coils, etc. In particular, an electronic component can be a power semiconductor or a power semiconductor module.

According to a preferred embodiment of the invention, the second plate is an isolating plate which electrically isolates the first printed circuit board from a second printed circuit board which is arranged between the second plate and the second side wall.

According to a preferred embodiment of the invention, the wall thickness of the rotary shaft designed as a hollow shaft lies in a value range of 0.5 to 5 mm, more preferably in a value range of 1 to 4 mm, even more preferably in a value range of 2 to 3 mm.

According to a preferred embodiment of the invention, the rotary shaft is composed axially of two or more individual parts. The rotary shaft is divided into two or more individual parts, preferably made of plastic. Using interchangeable inserts in a production tool, e.g. an injection mold, it is possible to produce different variants of the rotary shaft with different lengths with relatively little effort. This makes it possible to fulfil the desire for variability with regard to the length of the rotary shaft.

According to a preferred embodiment of the invention, the rotary shaft is composed of two or more individual parts which are snapped together.

According to a preferred embodiment of the invention, the rotary shaft is composed of a metal center piece, or middle piece, and two plastic end pieces. The rotary shaft is divided into three or more individual parts, wherein two end pieces are made of plastic and centrally a middle piece is made of steel. The length variability can be controlled by different lengths of the middle piece. This metal middle piece absorbs most of the torsional stress.

According to a preferred embodiment of the invention, the middle piece is a round steel with serrated ends. The middle piece can be made of a round steel with serrated ends so that it can be press-fitted firmly and in a torsion-proof manner with the end pieces.

According to a preferred embodiment of the invention, the middle piece is designed as a square rod that is loosely inserted into the end pieces.

According to a preferred embodiment of the invention, the metal part is inserted into the injection mold during the injection-molding process and is over-molded. The result is a metal-plastics hybrid part.

Although the invention is illustrated and described herein as being embodied in a switching device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a perspective view of a first step for mounting a conventional motor starter on a mounting base;

FIG. 2 shows a second step for mounting a conventional motor starter on a mounting base;

FIG. 3 shows a sectional view of a conventional motor starter mounted on a mounting base;

FIG. 4 shows a step for dismantling a conventional motor starter from a mounting base;

FIG. 5 shows a conventional rotary shaft;

FIG. 6 shows a section of a conventional motor starter parallel to the side walls;

FIG. 7A shows a section of a conventional motor starter parallel to the front wall taken along the line A-A in FIG. 5;

FIG. 7B shows a section of a conventional motor starter parallel to the front wall taken along the line B-B in FIG. 5;

FIG. 8 shows a section of a conventional switching device parallel to the front wall;

FIG. 9 shows a first section of a switching device according to the invention parallel to the front wall;

FIG. 10 shows a second section of a switching device according to the invention parallel to the front wall;

FIG. 11 shows three views of a two-part rotary shaft of a switching device according to the invention; and

FIG. 12 shows two views of a three-part rotary shaft of a switching device according to the invention.

### DETAILED DESCRIPTION OF THE INVENTION

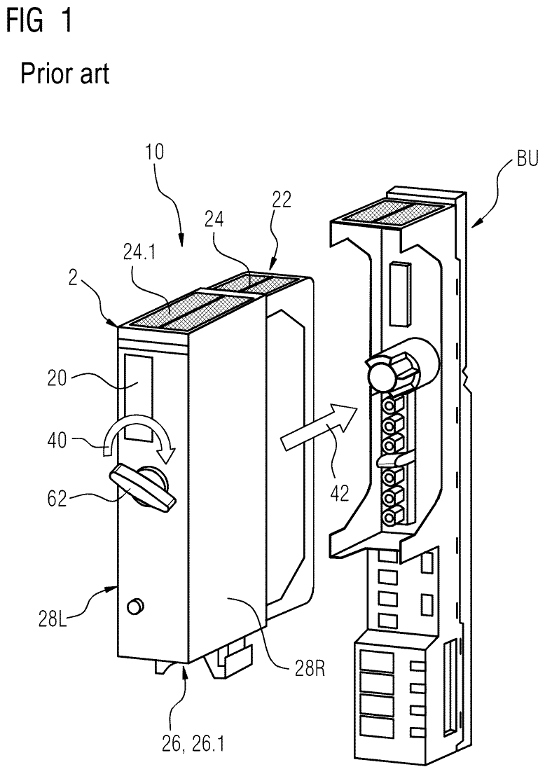

FIGS. 1 to 4 show a conventional switching device, namely a SIMATIC® ET 200SP motor starter, mounted on a corresponding, fully wired mounting base of a control cabinet, as described in the introduction above.

The switching device 10 has a housing 2 with a front wall 20, a rear wall 22 opposite the front wall 20, a top wall 24 and a bottom wall 26 opposite the top wall 24, and two opposite side walls 28L, 28R. An air duct 4 running parallel to the side walls 28L, 28R is formed in the housing 2 and has a clear width D, measured in a direction transverse to the side walls 28L, 28R. The top wall 24 and the bottom wall 26 each have ventilation openings 24.1, 26.1.

The switching device 10 has a rotary shaft 6, which is rotatably mounted in the front wall 20 and carries a rotary device 62 at its end projecting out of the housing 2 beyond the front wall 20, which rotary device is connected for conjoint rotation to the rotary shaft 6. This rotary device 62, which in the present exemplary embodiment is designed as a rotary toggle, is accessible from the outside of the front wall 20 to an operator of the switching device 10 who wishes to mount the motor starter 10 on a corresponding mounting base. The rotary shaft 6 is also rotatably mounted in the rear wall 22 and carries a coupling device 64 at its end projecting out of the housing 2 beyond the rear wall 22, which coupling device is connected for conjoint rotation to the rotary shaft 6. With the aid of the coupling device 64, the housing 2 of the switching device 10 can be attached to a corresponding mounting device BU, also referred to as: mounting base.

FIG. 1 shows a first step for mounting the motor starter 10 on the mounting base BU. First, the rotary shaft 6 of the motor starter 10 is rotated into a mounting/dismantling position by means of the rotary toggle 62 of the rotary shaft 6, as indicated by the arrow 40. The motor starter 10 is then guided onto the mounting base BU, as indicated by the arrow 42.

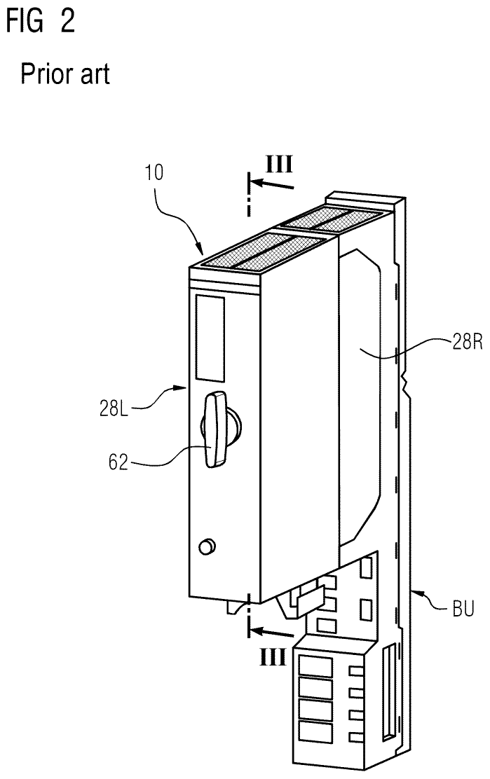

FIG. 2 shows a second step in which the rotary shaft 6 of the motor starter 10 has been brought into the operating position/READY: in this position, the motor starter 10 is firmly locked in the mounting base BU and all electrical contacts are connected.

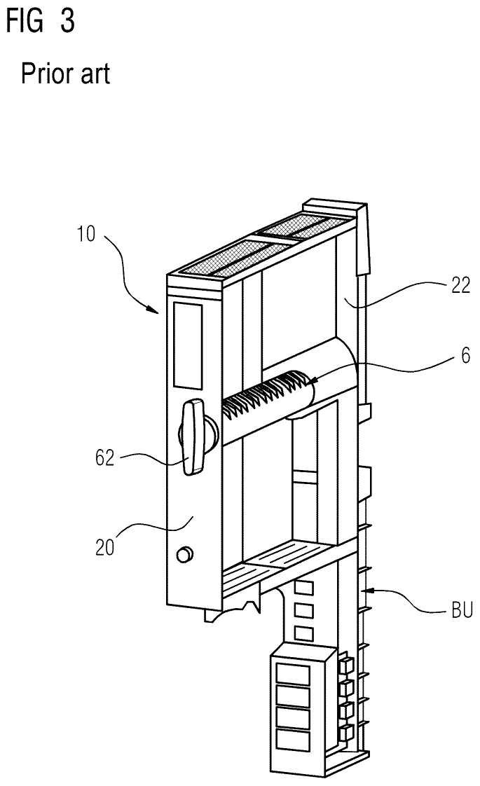

FIG. 3 shows the section III-III indicated in FIG. 2 parallel to the side walls 28L, 28R: inside the housing 10, the rotary shaft 6 can be seen, which serves to lock the motor starter 10 in the mounting base BU.

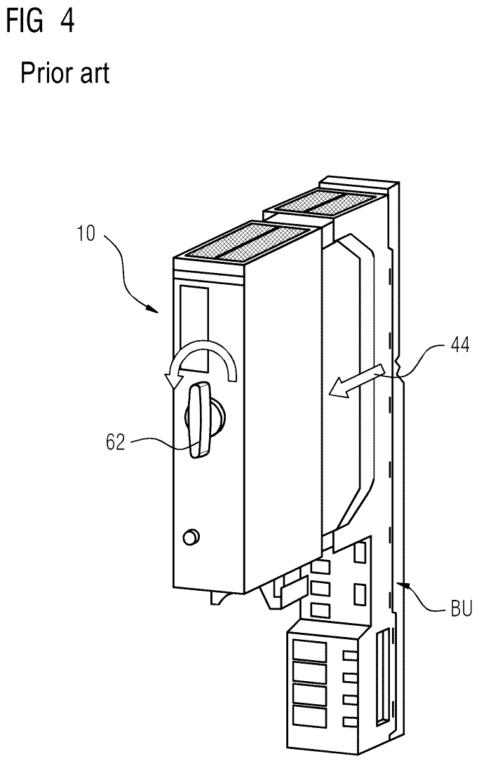

FIG. 4 shows a dismantling step, in which the motor starter 10 is again removed from the mounting base BU, as indicated by the arrow 44. To do this, the rotary shaft 6 of the motor starter 10 is turned back into the mounting/dismantling position, which pushes the motor starter 10 out of the mounting base BU, and then the motor starter 10 is pulled off from the mounting base BU. When the rotary shaft is rotated by actuating the rotary toggle, a torque of up to 2 Nm can act on the rotary shaft at times, which leads to mechanical stresses in the rotary shaft.

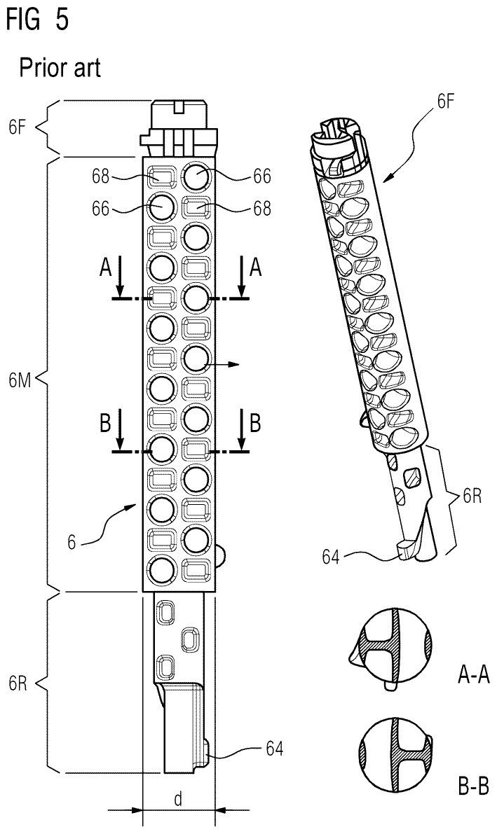

FIG. 5 shows a conventional rotary shaft 6. The rotary shaft 6 has a first end portion 6F, which can be rotatably mounted in the front wall 20 of a motor starter 10. The rotary shaft 6 has a second end portion 6R, which can be rotatably mounted in the rear wall 22 of a motor starter 10. At the end of its first end portion 6F, the rotary shaft 6 can carry a rotary device 62 which is connected for conjoint rotation to the rotary shaft 6 and which is accessible to an operator of the switching device 10 on the outside of the front wall 20. The rotary device 62 can be designed as a rotary toggle.

And at the end of its second end portion 6R, the rotary shaft 6 can carry a coupling device 64 which is connected for conjoint rotation to the rotary shaft 6 and by means of which the switching device 10 can be fastened to a corresponding holding device BU. The coupling device 64 can be designed as a retaining lug which can engage in a corresponding groove in the mounting base in the manner of a bayonet catch.

The rotary shaft 6 has a middle portion 6M, which is located between the first 6F and the second 6R end portion and which has an outer diameter d. When the rotary shaft 6 is mounted in the housing 2 of the switching device 10, this middle portion 6M is located in the air duct 4 of the switching device 10. B

When the rotary device 62, e.g. the rotary toggle, is actuated, torques of up to 2 Nm can occur at times, which lead to mechanical stresses in the rotary shaft 6. The rotary shaft 6 must be designed in such a way that it is not damaged during operation.

The relatively large distance between the front wall and rear wall of the base unit of >10 cm results in torsion of the rotary shaft. This torsion should be kept as small as possible to ensure functional safety.

The rotary shaft must not be electrically conductive and must have functional surfaces/contours at the ends (bayonet lock retaining lug on the shaft, which engages in a corresponding groove in the mounting base, driving pins, latches, etc.). Plastic is therefore a suitable material.

The following characteristics of conventional rotary shafts result from their design: To ensure strength and torsional rigidity, conventional rotary shafts have the largest possible diameter due to their length (>10 cm). However, the rotary shafts with their relatively large diameter block the cooling channel and prevent a good flow of cooling air through the housing.

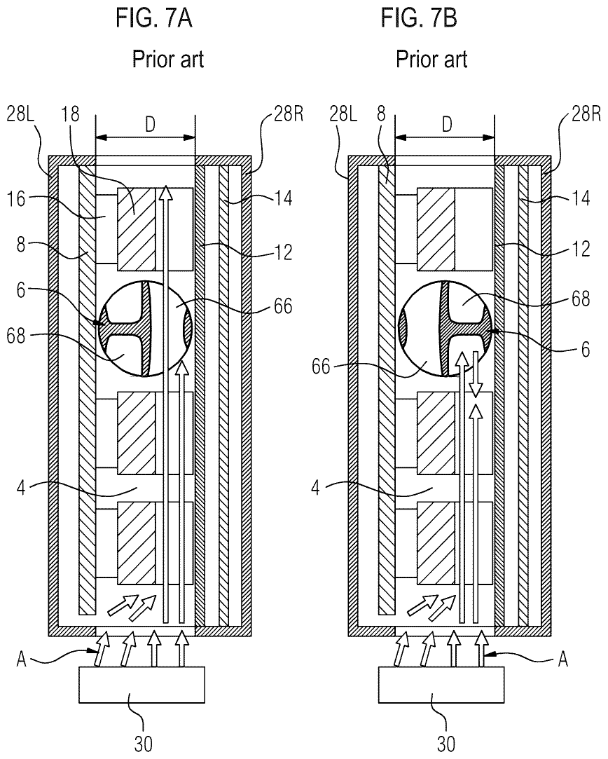

To improve the flow of cooling air through the housing, the rotary shaft 6 has continuous openings 66. However, these continuous openings 66 impair the torsional rigidity of the rotary shaft 6, as they greatly weaken the ideal cylinder contour. This weakening is compensated for by a further increase in the diameter of the rotary shaft 6, so that the space available for a cooling air flow through the air duct is severely restricted; see FIGS. 7A, 7B.

In addition to the continuous openings 66, the conventional rotary shaft 6 also has blind holes 68: these recesses serve to reduce the material thickness. The aim of this is to try and keep the cycle time for plastics injection molding of the rotary shaft 6 as short as possible. The continuous openings 66 can only ever be designed alternately with blind holes 68, which in turn results in a very strong restriction of the air flow through the air duct.

In addition to the vertical view of the rotary shaft 6 (left), FIG. 5 also shows an oblique view of the rotary shaft 6 (right) as well as two sections of the rotary shaft 6 transverse to its longitudinal axis: a section A-A and a section B-B, the position of which is indicated in the vertical view of the rotary shaft 6.

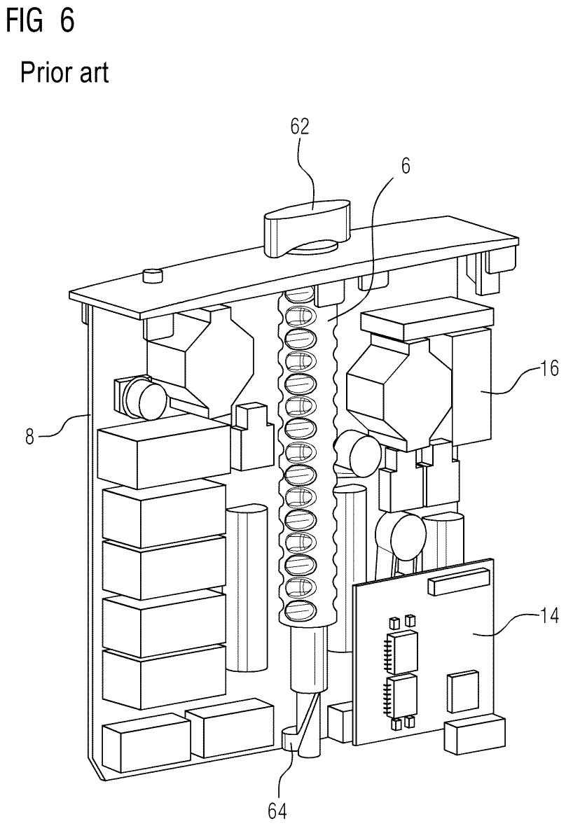

FIGS. 6, 7A, and 7B show sections of a conventional motor starter. The section shown in FIG. 6 runs parallel to the side walls. The sections shown in FIGS. 7A and 7B run parallel to the front wall. The air duct 4 is bounded on the one hand by a first printed circuit board 8 arranged in the housing parallel to a first 28L of the two side walls 28L, 28R, on which electronic components 16, e.g. power semiconductors, and heat sinks 18 arranged on the electronic components 16 are arranged. On the other hand, the air duct 4 is bounded by a second plate 12 arranged parallel to a second 28R of the two side walls 28L, 28R. Here, the second plate 12 is an isolating plate which electrically isolates the first printed circuit board 8 from a second printed circuit board 14 which is arranged between the second plate 12 and the second side wall 28R. The clear width D of the air duct 4 is defined here by the distance between the first printed circuit board 8 and the second plate 12.

When using thyristors, up to a certain starting current (e.g. 50 A for 6 sec), cooling of the thyristors via the first printed circuit board is sufficient (printed circuit board cooling). The heat output in the continuous current is limited, for example, via bypassed low-resistance relays. This eliminates the need for additional heat sinks. There is thus sufficient space inside the housing for a rotary shaft with a large diameter and large continuous openings 66; see FIG. 6.

There is thus sufficient space inside the housing for a rotary shaft with a large diameter and large continuous openings 66, as no further large-volume heat sinks are required; see FIG. 6.

The aim is therefore to achieve the largest possible diameter d of the rotary shaft 6, which is equipped with the largest possible continuous openings 66. This in turn means that the rotary shaft is completely in the air stream A, but the air stream can only pass through the continuous openings 66 of the rotary shaft to the opposite side of the rotary shaft. Due to the manufacturing process, the continuous openings 66 alternate with the blind holes 68, which leads to completely different flow behavior, as can be seen from the sections in FIGS. 7A and 7B. FIG. 7A on the left shows a section in plane A-A of the rotary shaft as shown in FIG. 5 and FIG. 7B on the right shows a section in plane B-B of the rotary shaft as shown in FIG. 5. The left section 7A shows a rotary position of the rotary shaft 6 in which a relatively small air stream can pass through the rotary shaft 6. The right section 7B shows a rotary position of the rotary shaft 6 in which the air stream is completely blocked by the rotary shaft 6.

The large-volume rotary shaft continues to limit the available installation space. The possibility of using heat sinks is extremely limited.

At low flows with low heat release, heat dissipation via free convection is sufficient; at higher flows with increased heat release, a fan 30 is also used, which causes forced convection.

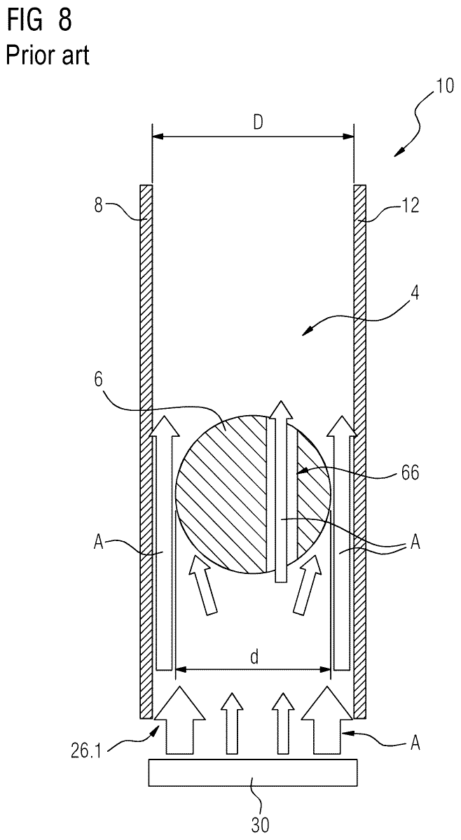

FIG. 8 shows a section of a conventional switching device 10 parallel to the front wall of the housing of the motor starter 10. The clear width D of the air duct 4 is defined here by the distance between the first printed circuit board 8 and the second plate 12. A solid rotary shaft 6 with an outer diameter d extends through the middle of the air duct 4. The ratio D/d is approximately 1.3. The rotary shaft 6 has one or more continuous openings 66 through which a portion of the air stream A entering through a ventilation opening 26.1 of the bottom wall, driven by a fan 30, can flow. Another part of this air stream A passes between the outer sides of the rotary shaft 6 and the walls 8, 12 delimiting the air duct 4. Overall, a relatively large part of the air stream A is blocked by the rotary shaft 6.

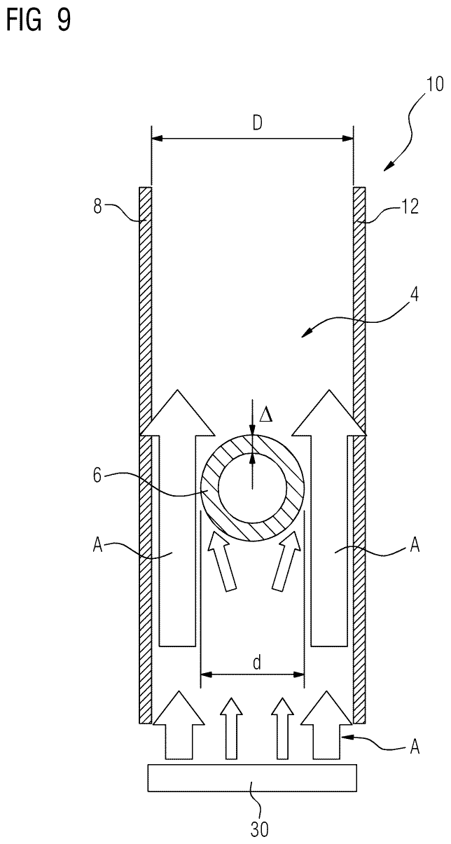

FIG. 9 shows a first section of a switching device 10 according to the invention parallel to the front wall of the housing of the motor starter 10. The clear width D of the air duct 4 is defined here by the distance between the first printed circuit board 8 and the second plate 12. A hollow rotary shaft 6 with an outer diameter d, which is considerably smaller than the outer diameter D of the conventional rotary shaft shown in FIG. 8, extends in the middle of the air duct 4. The ratio D/d is approximately 2. A substantial portion, approximately 50%, of an air stream A entering the air duct 4 through a ventilation opening 26.1 of the bottom wall, driven by a fan 30, can pass between the outer sides of the rotary shaft 6 and the walls 8, 12 bounding the air duct 4. Overall, a relatively small part of the air stream A is blocked by the rotary shaft 6.

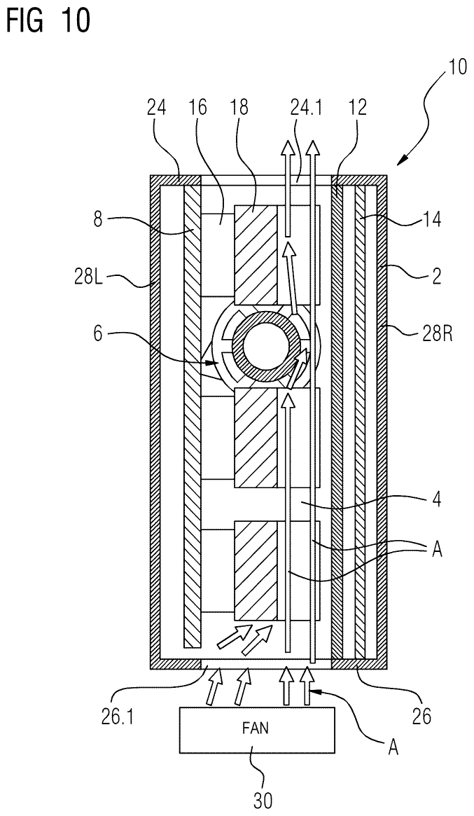

FIG. 10 shows a second section of a switching device 10 according to the invention parallel to the front wall. The switching device 10 has a housing 2 with a top wall 24 and a bottom wall 26 opposite the top wall 24, and two opposing side walls 28L, 28R. The top wall 24 and the bottom wall 26 each have ventilation openings 24.1, 26.1, through which an air stream A generated by a fan 30 can enter or exit. An air duct 4 running parallel to the side walls 28L, 28R is formed in the housing 2 and has a clear width D, measured in a direction transverse to the side walls 28L, 28R.

The air duct 4 is bounded on the one hand by a first printed circuit board 8 arranged in the housing parallel to a first 28L of the two side walls 28L, 28R, on which electronic components 16 and heat sinks 18 are arranged, and on the other hand by a second plate 12 arranged parallel to a second 28R of the two side walls 28L, 28R, wherein the clear width D of the air duct 4 is defined by the distance between the first printed circuit board 8 and the second plate 12. The second plate 12 is an isolating plate which electrically isolates the first printed circuit board from a second printed circuit board which is arranged between the second plate and the second side wall.

The switching device 10 comprises a rotary shaft 6, which is rotatably mounted in the front wall 20. The rotary shaft 6 is also rotatably mounted in the rear wall 22.

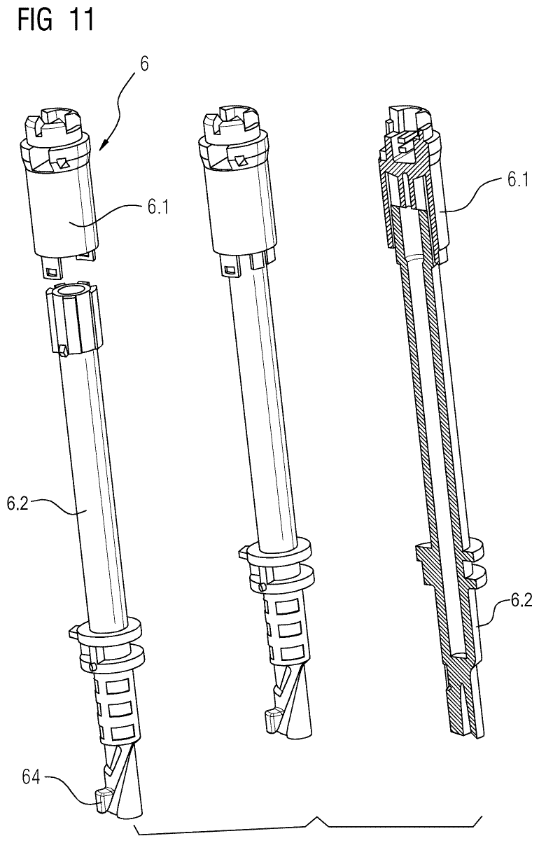

FIG. 11 shows three views of a two-part rotary shaft 6 of a switching device according to the invention. The rotary shaft 6 is divided into two individual parts 6.1, 6.2 made of plastic and designed as hollow shafts. Using interchangeable inserts in the injection-molding tool, different variants with different lengths can be realized with relatively little effort. This makes it possible to fulfil the desire for variability in terms of length.

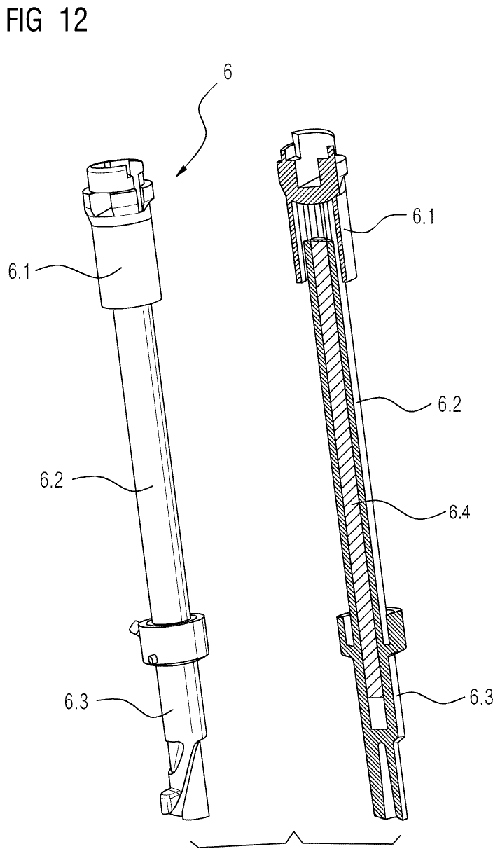

FIG. 12 shows two views of a variation of the rotary shaft 6 of a switching device according to the invention. The rotary shaft 6 is shown as three parts 6.1, 6.2, 6.3: The middle piece 6.2, or intermediate piece, and the end piece 6.3 are integrally formed as a single plastic element. The intermediate piece 6.2 is a plastics-metal hybrid part (=composite material=compound) in the middle. The intermediate piece is also referred to as the middle piece. The metal intermediate piece 6.4 is fed to the injection-molding machine as an insert during the injection-molding process and the metal piece 6.4 is covered by the plastics of the intermediate piece 6.2 and, in part, by the end piece 6.3.

In a further embodiment, an intermediate piece 6.2 made of steel is used. The intermediate piece 6.2 can be made of a round steel with serrated ends, for example, so that it is press-fitted firmly and in a torsion-proof manner with the end pieces. Alternatively, the intermediate piece 6.2 can be designed as a square steel pin that is inserted loosely into the end pieces 6.1, 6.3. The length variability can be controlled by different lengths of the intermediate piece 6.2.

It is possible that the intermediate piece 6.2 comprises a metal pin 6.4 or rod encased in a plastics sheath.

1. A switching device, comprising:
a housing having a front wall, a rear wall opposite said front wall, a top wall and a bottom wall opposite the top wall, and two opposing side walls, and wherein an air duct is formed in said housing running parallel to said side walls and having a clear width D, measured in a direction transverse to said side walls;
a rotary shaft extending from said front wall, through said housing, and to said rear wall, said rotary shaft having a first end portion rotatably mounted said front wall and a second end portion rotatably mounted in said rear wall;
said rotary shaft carrying a rotary device at an end of said first end portion which is connected for conjoint rotation with said rotary shaft and which is accessible on an outer side of said front wall, and said rotary shaft carrying a coupling device at an end of said second end portion which is connected for conjoint rotation with said rotary shaft and which is configured for fastening the switching device to a corresponding receiving device;
each of said bottom wall and said top wall being formed with at least one ventilation opening, enabling an air stream to flow in said air duct from said ventilation opening of said bottom wall to said ventilation opening of the top wall;
said rotary shaft having a middle portion between said first and second end portions, and extending in said air duct;
said middle portion of said rotary shaft having an outer diameter d; and
said rotary shaft being a hollow shaft and a ratio D/d of the clear width D of the air duct to the outer diameter d is greater than 1.5.

2. The switching device according to claim 1, wherein the ratio D/d lies between 1.8 and 2.2.

3. The switching device according to claim 1, wherein said air duct is bounded on one side by a first printed circuit board arranged in said housing parallel to a first of said two side walls and carrying electronic components and heat sinks, and said air duct is bounded on another side by a second plate arranged parallel to a second of said two side walls, and wherein the clear width D of said air duct is defined by a distance between said first printed circuit board and said second plate.

4. The switching device according to claim 3, wherein said second plate is an isolating plate configured to electrically insulate said first printed circuit board from a second printed circuit board disposed between said second plate and said second side wall.

5. The switching device according to claim 1, wherein a wall thickness of said hollow rotary shaft lies within a value range of 2 to 3 mm.

6. The switching device according to claim 1, wherein said rotary shaft is composed axially of two or more individual parts.

7. The switching device according to claim 1, wherein said rotary shaft is composed of two or more individual parts that are snapped together.

8. The switching device according to claim 1, wherein said rotary shaft is composed of a metal middle piece and two plastics end pieces.

9. The switching device according to claim 8, wherein said middle piece is a round steel rod formed with serrated ends.

10. A method for producing a rotary shaft for the switching device according to claim 1, the method comprising:
feeding a metal middle piece to an injection-molding machine as an insert part during an injection-molding process; and
injection-molding a plastics end piece onto the metal middle piece at each end thereof.
